(19) United States
(12) Patent Application Publication
(10) Pub. No.: US 2007/0023917 A1
(43) Pub. Date: Feb. 1, 2007

(54) Semiconductor device having multilayer wiring lines and manufacturing method thereof

(75) Inventor: Masaki Yamada, Saitama-shi (JP)

Correspondence Address: FOLEY AND LARDNER LLP;SUITE 500, 3000 K STREET NW, WASHINGTON, DC, 20007, US

(73) Assignee: KABUSHIKI KAISHA TOSHIBA

(21) Appl. No.: 11/493,928

(22) Filed: Jul. 27, 2006

(30) Foreign Application Priority Data
Jul. 28, 2005 (JP) 2005-218444

(51) Int. Cl. H01L 23/48

(52) U.S. Cl. 257/762

(57) ABSTRACT

A plurality of wiring layers made from a conductive material are formed in the same level layer on a substrate. A plurality of cavity layers are formed in the same level layer as the plurality of wiring layers. The plurality of cavity layers have a cavity ratio which is not smaller than 60%. An interlayer insulating film is formed on the plurality of wiring layers and on the plurality of cavity layers. A barrier metal, an oxygen barrier layer and an insulating layer are formed on side walls of the plurality of wiring layers.

### CROSS-REFERENCE TO RELATED APPLICATIONS

This application is based upon and claims the benefit of priority from prior Japanese Patent Application No. 2005-218444, filed Jul. 28, 2005, the entire contents of which are incorporated herein by reference.

### BACKGROUND OF THE INVENTION

1. Field of the Invention

The present invention relates to a semiconductor device having multilayer wiring lines and a manufacturing method thereof.

2. Description of the Related Art

Miniaturization of an element has advanced for the purpose of high integration of an LSI, and a wiring delay due to an increase in parasitic capacitance between wiring lines has become prominent owing to miniaturization of a wiring configuration. As a result, an influence on an LSI high-speed operation cannot be ignored.

In order to improve the wiring delay, there has been examined realization of a low dielectric constant of an interlayer insulating film by changing a wiring material from a conventionally used aluminum-based alloy to copper having a lower resistance and insulating wiring lines from each other. There has been developed a technology which uses methyl siloxane which has a relative dielectric constant lower than that of a fluoridated silicon dioxide film and is obtained by a CVD (Chemical Vapor Deposition method) method or spin coating as the interlayer insulating film.

However, with a recent improvement in integration, a relative dielectric constant must be further reduced, and a method which uses methyl siloxane or a porous low-dielectric-constant film obtained by providing cavities in methyl siloxane in a space between wiring lines has been proposed (see, e.g., Jpn. Pat. Appln. KOKAI Publication No. 2003-347401). As an ultimate inter-wiring structure having a low dielectric constant, there is an aerial wiring structure in which a cavity ratio of a space between wiring lines is 100% (see, e.g., Jpn. Pat. Appln. KOKAI Publication No. 9-237831).

On the other hand, as a cavity ratio of the low-dielectric-constant film is increased, mechanical strength which supports wiring lines and short circuit between wiring lines due to diffusion of a wiring metal into cavities of the low-dielectric-constant film become a problem. Further, there is another problem that short circuit between wiring lines occurs due to a small film remaining on a wall surface of a cavity layer when forming cavities.

### BRIEF SUMMARY OF THE INVENTION

According to a first aspect of the present invention, there is provided a semiconductor device comprising: a plurality of wiring layers made from a conductive material which are formed in the same level layer on a substrate; a plurality of cavity layers formed in the same level layer as the plurality of wiring layers, the plurality of cavity layers having a cavity ratio which is not smaller than 60%; an interlayer insulating film formed on the plurality of wiring layers and the plurality of cavity layers; and a barrier metal, an oxygen barrier layer and an insulating layer formed on side walls of the plurality of wiring layers.

According to a second aspect of the present invention, there is provided a semiconductor device comprising: a plurality of first wiring layers formed in a first level layer on a substrate; a first barrier metal, a first oxygen barrier layer and a first insulating layer formed on side walls of the plurality of first wiring layers; a plurality of first cavity layers formed between the plurality of first wiring layers, the first cavity layers having a cavity ratio which is not smaller than 60%; a plurality of second wiring layers formed in a second level layer above the first level layer on the substrate; a second barrier metal, a second oxygen barrier layer and a second insulating film formed on side walls of the plurality of second wiring layers; a plurality of second cavity layers formed between the plurality of second wiring layers, the second cavity layers having a cavity ratio which is not smaller than 60%; an interlayer insulating film formed between the first level layer and the second level layer, the interlayer insulating film insulating the plurality of first wiring layers from the plurality of second wiring layers from each other; and a plug member formed in the interlayer insulating film, the plug member electrically connects the first wiring layer with the second wiring layer with each other.

According to a third aspect of the present invention, there is provided a manufacturing method of a semiconductor device, comprising: depositing a dummy film on a substrate; forming a wiring groove in the dummy film; forming a metal layer on a side wall in the wiring groove; forming an oxygen barrier layer on the metal layer on the side wall in the wiring groove; forming a barrier metal on the oxygen barrier layer on the side wall in the wiring groove; forming a wiring layer on the barrier metal in the wiring groove; forming an interlayer insulating film above the wiring layer; vaporizing the dummy film by a heat treatment after formation of the interlayer insulating film, forming a cavity layer having a cavity ratio which is not smaller than 60% and oxidizing the metal layer to form an insulating layer.

### BRIEF DESCRIPTION OF THE SEVERAL VIEWS OF THE DRAWING

FIG. 1 is a cross-sectional view showing a configuration of a semiconductor device according to Embodiment 1 of the present invention;

FIGS. 2A and 2B are cross-sectional views showing a first step of a manufacturing method of the semiconductor device according to Embodiment 1 of the present invention;

FIGS. 3A and 3B are cross-sectional views showing a second step of the manufacturing method of the semiconductor device according to Embodiment 1 of the present invention;

FIGS. 4A and 4B are cross-sectional views showing a third step of the manufacturing method of the semiconductor device according to Embodiment 1 of the present invention;

FIG. 5 is a cross-sectional view showing a fourth step of the manufacturing method of the semiconductor device according to Embodiment 1 of the present invention;

FIGS. 6A and 6B are cross-sectional views showing a fifth step of the manufacturing method of the semiconductor device according to Embodiment 1 of the present invention;

FIG. 7 is a cross-sectional view showing a sixth step of the manufacturing method of the semiconductor device according to Embodiment 1 of the present invention;

FIG. 8 is a cross-sectional view showing a seventh step of the manufacturing method of the semiconductor device according to Embodiment 1 of the present invention;

FIG. 9 is a cross-sectional view showing a configuration of a semiconductor device according to a modification of Embodiment 1 of the present invention;

FIG. 10 is a cross-sectional view showing a configuration of a semiconductor device according to Embodiment 2 of the present invention;

FIGS. 11A and 11B are cross-sectional views showing a first step of the manufacturing method of the semiconductor device according to Embodiment 2 of the present invention;

FIGS. 12A and 12B are cross-sectional views showing a second step of the manufacturing method of the semiconductor device according to Embodiment 2 of the present invention;

FIG. 13 is a cross-sectional view showing a third step of the manufacturing method of the semiconductor device according Embodiment 2 of the present invention;

FIGS. 14A and 14B are cross-sectional views showing a fourth step of the manufacturing method of the semiconductor device according to Embodiment 2 of the present invention;

FIG. 15 is a cross-sectional view showing a fifth step of the manufacturing method of the semiconductor device according to Embodiment 2 of the present invention;

FIG. 16 is a cross-sectional view showing a sixth step of the manufacturing method of the semiconductor device according to Embodiment 2 of the present invention; and

FIG. 17 is a cross-sectional view showing a configuration of a semiconductor device according to a modification of Embodiment 2 of the present invention.

### DETAILED DESCRIPTION OF THE INVENTION

Embodiments according to the present invention will now be described hereinafter.

### Embodiment 1

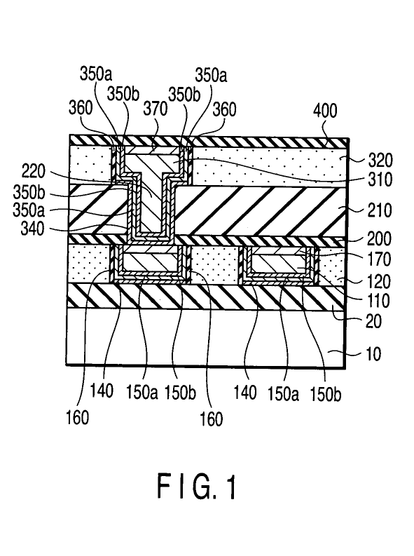

Embodiment 1 according to the present invention will now be described with reference to FIGS. 1 to 9.

FIG. 1 is a cross-sectional view schematically showing a configuration of a semiconductor device in Embodiment 1 according to the present invention. However, it should be noted that the drawing is a schematic representation and a relationship between a thickness and a plane dimension and a thickness or a ratio of each layer are different from actual values. In Embodiment 1, an example of the most simple two-layer wiring line of multilayer wiring lines is schematically shown.

A configuration of a semiconductor device according to Embodiment 1 is as follows. For example, an element or the like (not shown) formed of, e.g., a transistor, a capacitor, an element isolation region and others is provided on a substrate 10 made from, e.g., silicon. An upper part of this element is covered with a first interlayer insulating film 20 made from, e.g., a silicon oxide film having a film thickness of, e.g., approximately 500 nm, and flattened.

On this first interlayer insulating film 20, a first wiring layer 110 having, e.g., copper embedded therein and a first cavity layer 120 having a cavity ratio which is not smaller than 60% are provided in the same level layer. 60% or more of a volume of the cavity layer 120 is cavities.

At a side wall portion which is a boundary region between the first wiring layer 110 and the first cavity layer 120, a second titanium layer 150b as a barrier metal suppressing diffusion of copper or the like, a first titanium nitride layer 150a suppressing oxidation and a first titanium oxide layer 160 as an insulating layer on an outer side are provided in the order from the side adjacent to the first wiring layer 110. This first titanium oxide layer 160 is provided on the side wall of the first wiring layer 110 which is in contact with the first cavity layer 120, and has an effect of improving insulating resistance properties between wiring lines. As the insulating layer, it is possible to use, e.g., titanium oxide, tantalum oxide, aluminum oxide, silicon nitride, silicon oxide or silicon carbide. As the barrier metal, it is possible to adopt, e.g., titanium, titanium nitride, tantalum or tantalum nitride. Moreover, in the wiring layer having the first wiring layer 110, the second titanium layer 150b and the first titanium layer 150a, a thin first titanium layer 140 is provided on a bottom surface which is in contact with the first interlayer insulating film 20.

A first anti-diffusion layer 170 which suppresses diffusion of copper or the like which is a wiring portion material forming the first wiring layer 110 is provided at an upper end of the first wiring layer 110. An upper end of the first anti-diffusion layer 170 is set to become level with the first cavity layer 120.

Upper sides of the first wiring layer 110 and the first cavity layer 120 are covered with a second interlayer insulating film 200 made of, e.g., a silicon oxide film, and flattened. With the above-described arrangement, a first wiring level formed in the same level layer is constituted.

A first silicon base oxide film 210 having a low dielectric constant is deposited on the second interlayer insulating film 200. A plug member 220 having copper or the like embedded therein is provided above the first anti-diffusion film 170 in the first silicon base oxide film 210.

A second wiring level having a second wiring layer 310 and a second cavity layer 320 is provided on the first silicon base oxide film 210.

The second wiring layer 310 is electrically connected with the first wiring layer 110 through the plug member 220 and the first anti-diffusion film 170.

On a side wall part of the plug member 220, a fourth titanium layer 350b as a barrier metal suppressing diffusion of copper, a second titanium nitride layer 350a as an oxygen barrier layer and a third titanium layer 340 on an outer side are formed in the order from the side which is in contact with copper embedded in the plug member.

The second wiring level has the same configuration as the first wiring level. Specifically, at a boundary part between the second wiring layer 310 and the second cavity layer 320, the fourth titanium layer 350b as a barrier metal suppressing diffusion of copper or the like, the second titanium nitride layer 350a as an oxygen barrier layer suppressing oxidation and a second titanium oxide layer 360 as an insulating layer on an outer side are provided in the order from the side adjacent to the second wiring layer 310. This second titanium oxide layer 360 is provided on a side wall with respect to the second cavity layer 320, and has an effect of improving insulating resistance properties between wiring layers.

A second anti-diffusion film 370 which suppresses diffusion of copper or the like is provided at an upper end of the second wiring layer 310. An upper end of the second anti-diffusion film 370 is set to become level with the second cavity layer 320.

Upper sides of the second wiring layer 310 and the second cavity layer 320 are covered with a third interlayer insulating film 400 made of, e.g., a silicon oxide film, and flattened. With the above-described arrangement, the second wiring level formed in the same level layer is constituted.

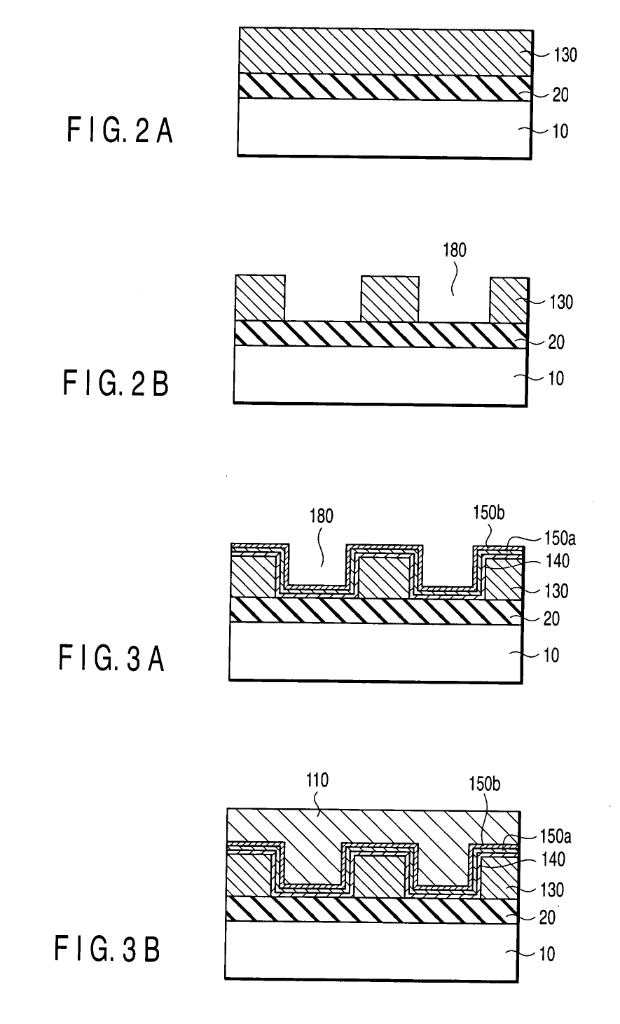

A manufacturing method of the semiconductor device in this embodiment will now be described with reference to process cross-sectional views of FIGS. 2A to 8. In these process cross-sectional views, element isolation and MOSFET forming steps are eliminated, and steps directly concerning a method of forming multilayer wiring lines alone will be described.

First, as shown in FIG. 2A, a device (not shown) formed of an element isolation, an MOSFET and others is formed on the silicon substrate 10, and a BPSG (Boron-doped Phospho-Silicate Glass) film having boron and phosphor doped as impurities therein is formed with a film thickness of, e.g., approximately 500 nm by, e.g., a CVD (Chemical Vapor Deposition) method as the first interlayer insulating film 20 serving as an insulated separation layer on the substrate.

Then, for example, a first carbon film 130 as the first dummy film is deposited to have a film thickness of approximately 200 nm on the first interlayer insulating film 20 (see FIG. 2A). This first dummy film 130 is used to form a cavity portion by a heat treatment later. As this first dummy film 130, a carbon film or the like formed by, e.g., a sputtering method or a CVD method is preferable. This first dummy film 130 may be, e.g., a graphite film or an organic film containing a large amount of carbon in place of the carbon film. It is preferable to vaporize a part or all of the carbon film or the like formed at this step by a later-performed heat treatment.

Then, a silicon oxide film (not shown) as a hard mask is deposited on the first carbon film 130, and a resist (not shown) is applied to an upper side of this film. Thereafter, a regular photoresist technique is used to form a resist pattern. The silicon oxide film serving as a mask is patterned by using a dry etching method or the like with this resist pattern being used as a mask. Subsequently, the resist pattern is removed.

Then, the first carbon film 130 is processed by using, e.g., an RIE (Reactive Ion Etching) method with the patterned silicon oxide film being used as a mask (not shown), thereby forming each groove portion 180 which is a wiring groove used to form a wiring layer (see FIG. 2B).

Subsequently, the first titanium layer 140, the first titanium nitride layer 150a and the second titanium layer 150b are deposited on an entire surface of each groove portion 180 including a bottom wall portion and a side wall portion (see FIG. 3A). At this time, the first titanium layer 140 which is formed on the side wall portion of the groove portion 180 and is in contact with the first carbon film 130 is oxidized to become a first titanium oxide film when performing a heat treatment later, and has an effect of improving insulating resistance properties between wiring lines. The first titanium nitride layer 150a has an effect as an oxygen barrier layer which prevents oxygen from being transmitted therethrough in a heat treatment in an oxidizing atmosphere. The second titanium layer 150b has an effect as a barrier metal which suppresses diffusion of copper or the like as a wiring layer.

As a method of forming a three-layer structure made of the first titanium layer 140, the first titanium nitride layer 150a and the second titanium layer 150b, it is preferable to use an ALCVD (Atomic Layer CVD) method or a sputtering method by which these layers are uniformly deposited on the bottom portion and the side wall portion of each groove portion. Moreover, as film thicknesses of the first titanium layer 140, the first titanium nitride layer 150a and the second titanium layer 150b to be formed, approximately 5 nm, 1 nm and 5 nm are preferable, respectively. That is because a film thickness of approximately 5 nm allows sufficient formation of the films when forming the first titanium layer 140 and the second titanium layer 150b by using the sputtering layer. In case of forming the first titanium nitride layer 150a by using the ALCVD method, a film thickness of approximately 1 nm allows sufficient formation of the film. It is to be noted that a specific resistance of the second titanium layer 150b as the barrier metal is at least double-digit higher than that of copper which is a main metal of wiring lines. Since a wiring resistance is increased when a film thickness of the barrier metal in the wiring lines becomes large, it is preferable to set a film thickness of the second titanium layer 150b as small as possible.

Then, the conductive first wiring layer 110 made from, e.g., copper is deposited on the second titanium layer 150b to completely fill each groove portion 180 (see FIG. 3B).

Subsequently, a surface of the first wiring layer 110 is flattened by using, e.g., a CMP (Chemical Mechanical Polishing) method until the first wiring layer 110 has the same height as an upper end of the first carbon film 130. At this time, the first titanium layer 140, the first titanium nitride layer 150a and the second titanium layer 150b deposited on the first carbon film 130 are removed.

Then, a recess process is performed with respect to an upper end portion of the first wiring layer 110. The recess process is one of selective etching methods, and the following procedure is used when the first wiring layer 110 is, e.g., copper.

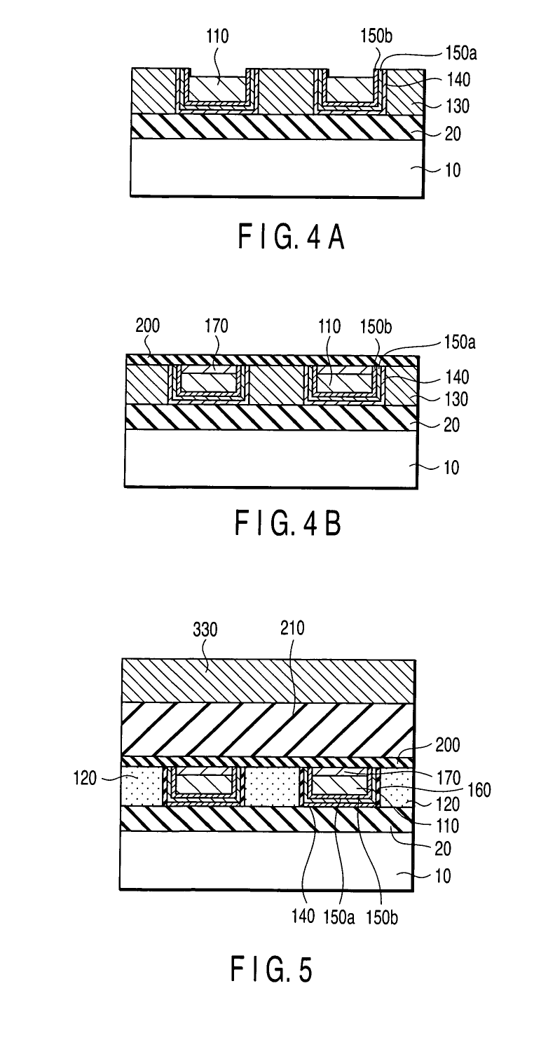

First, diluted ammonia is used to oxidize a copper surface of the first wiring layer 110 to form copper oxide. This copper oxide is etched by using, e.g., hydrochloric acid. At this time, as a thickness of the surface of copper to be etched, approximately 20 to 30 nm is preferable (see FIG. 4A).

Subsequently, the first anti-diffusion film 170 serving as an anti-diffusion film of copper which is a wiring material is selectively deposited on an upper end portion of the first wiring layer 110 etched by the recess process. As this anti-diffusion film 170, Co is used, for example. Additionally, besides Co, it is possible to use CoW, CoWB, CoWP, SiN, SiCN, SiC or the like as the first anti-diffusion film 170.

Then, the second interlayer insulating film 200 is deposited on upper surfaces of the first anti-diffusion film 170 and the first carbon film 130 (see FIG. 4B). Here, as the second interlayer insulating film 200, a film which has a low relative dielectric constant and mechanical strength to withstand a weight of the second wiring level or the like formed on the second interlayer insulating film 200 is preferable. For example, as the second interlayer insulating film, a silicon oxide film, a porous silicon oxide film, methyl siloxane or the like can be formed by a CVD method or a coating method.

Here, a heat treatment is applied to the semiconductor substrate 10 in an oxygen atmosphere. The first carbon film 130 is vaporized through the second interlayer insulating film 200 by this heat treatment, thereby forming the first cavity layer 120. During this heat treatment, the side wall portion of the first titanium layer 140 which is in contact with the first carbon film 130 is simultaneously oxidized by the oxidization atmosphere, thus forming the first titanium oxide layer 160 (see FIG. 5). In this example, the first titanium oxide layer 160 may be a titanium-rich titanium oxide layer whose surface alone is oxidized. When the first titanium oxide layer 160 is formed in this manner, the first carbon film 130 is not completely vaporized in the first cavity layer 120, and a small amount of a conductive material remains on the side wall or the upper edge and lower edge portions of the first cavity layer 120. Even in a case where such a remaining small amount of the conductive material can be a factor of short circuit between wiring lines, there can be obtained an effect of improving insulation properties between the two adjacent wiring layers provided at both ends of the first cavity layer 120. That is, forming the first titanium oxide layer 160 on the side wall between the wiring lines can obtain an effect of improving reliability of the wiring lines without producing, e.g., a short-circuit defect between the wiring lines.

Thereafter, the first silicon base oxide film 210 is formed on the second interlayer insulating film 200, and a second carbon film 330 having a film thickness of approximately 200 mm is formed on the first silicon base oxide film 210 (see FIG. 5).

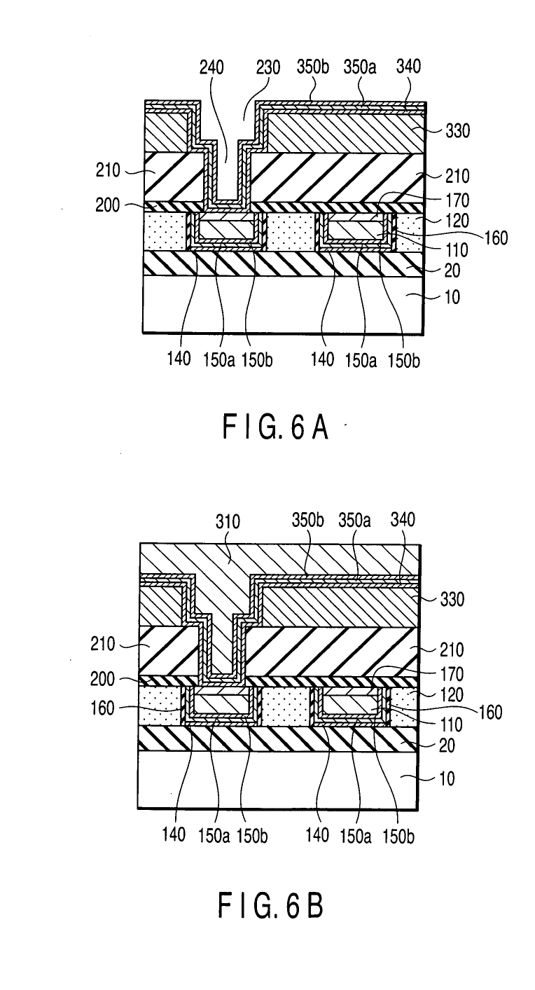

Subsequently, a regular lithography method and a regular etching method are used to form a groove portion 230 which is used to form the second wiring layer in the second carbon film 330 as shown in FIG. 6A. Additionally, a connection hole 240 which is required to form a plug member is formed in the first silicon base oxide film 210 and the second interlayer insulating film 200 below the groove portion 230. This connection hole 240 is formed immediately above the first wiring layer 110 and the first anti-diffusion layer 170, and has a shape reaching the first anti-diffusion film 170.

Then, the third titanium layer 340 is deposited on entire surfaces of the groove portion 230 and the connection hole 240 including inner walls thereof, and the second titanium nitride layer 350 and the fourth titanium layer 350b are deposited on the third titanium layer 340.

A side wall portion of the third titanium layer 340 which is in contact with the second carbon film 330 is oxidized when performing a heat treatment in an oxidation atmosphere later to become a second titanium oxide film, and has an effect of improving insulating resistance properties between wiring lines. The second titanium nitride layer 350a has an effect as an oxygen barrier layer which suppresses oxidation in the heat treatment in the oxidizing atmosphere. The fourth titanium layer 350b has an effect as a barrier metal which avoids diffusion of copper or the like which is a wiring layer.

Then, the second wiring layer 310 which serves as the second wiring layer and is made from, e.g., copper is deposited on an entire upper surface of the fourth titanium layer 350b (see FIG. 6B).

Subsequently, the second wiring layer 310 is flattened by using a CMP method or the like until the second wiring layer 310 becomes level with the upper end portion of the second carbon film 330. At this time, the fourth titanium layer 350b, the second titanium nitride layer 350a and the third titanium layer 340 deposited on the second carbon film 330 are removed.

Further, the recess process is performed with respect to an upper end portion of the second wiring layer 310 like the first wiring layer 110 to selectively deposit the second anti-diffusion film 370 serving as an anti-diffusion film of copper.

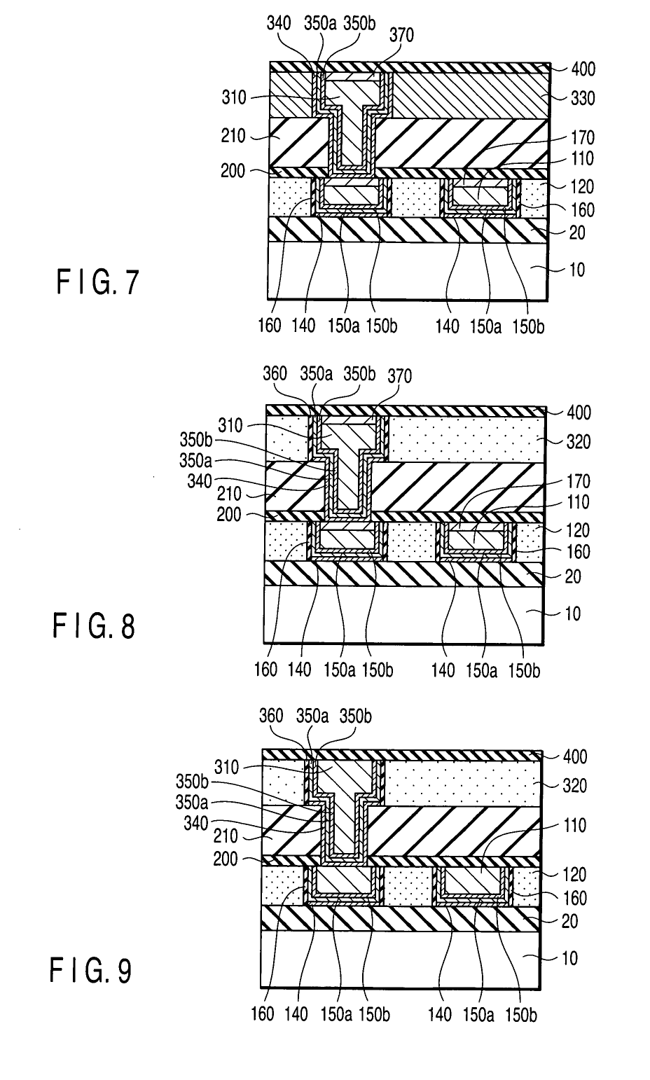

Then, the third interlayer insulating film 400 formed of, e.g., a silicon oxide film is formed on entire upper surfaces of the second anti-diffusion film 370 and the second carbon film 330 (see FIG. 7).

Subsequently, a heat treatment is performed with respect to the semiconductor substrate 10 in an oxygen atmosphere. The second carbon film 330 is burned by this heat treatment, thereby forming the second cavity layer 320. A side wall portion of the third titanium layer 340 which is in contact with the second cavity layer 320 is also oxidized simultaneously with this heat treatment, thus forming the second titanium oxide layer 360 (see FIG. 8). At this time, in the second titanium oxide layer 360, the third titanium layer 340 may not be completely oxidized, and a part of the third titanium layer 340 alone may be oxidized. Adopting the above-described method can form the second wiring level.

Although the description has been given as to the example in which the two wiring layers are provided in this embodiment, the present invention can be applied to a single wiring layer. In case of three or more wiring layers, multiple wiring layers made of three or more layers can be formed by repeating the steps shown in FIGS. 5 to 8 for a predetermined number of times.

Forming the titanium oxide layer on the side wall of the wiring layer which is in contact with the cavity layer in each wiring layer based on the method according to this embodiment can suppress electrical short circuit between the wiring layers adjacent to each other with the cavity layer therebetween.

It is to be noted that titanium is used for the barrier metal of the wiring layer side wall, it is possible to use, e.g., tantalum or tantalum oxide as long as it is a material having an effect of likewise suppressing diffusion of copper in place of titanium.

Furthermore, although titanium nitride is used for the oxygen barrier layer in this embodiment, it is possible to use any other material as long as it likewise has an effect as a diffusion barrier for oxygen and has a small electrical resistance besides titanium nitride. For example, aluminum nitride, tantalum nitride, tungsten nitride, silicon nitride silicon carbide or the like can be used as the oxygen barrier layer.

Moreover, although titanium is formed on the side wall of the cavity layer and oxidized titanium oxide is used for the insulating layer in this embodiment, it is possible to use any other material which has a small electrical resistance before oxidization like titanium and has excellent insulating properties when oxidized. There is, e.g., a method which forms, e.g., tantalum as such a material and oxidizes this material to be used as tantalum oxide, a method which forms aluminum and oxidizes this material to be used as aluminum oxide, or a method which forms conductive silicon and oxidizes this material to be used as silicon oxide.

Additionally, although the cavity layer forming method has been described on the case where the carbon film is used to form cavities between wiring lines by the heat treatment in this embodiment, the present invention is not restricted to the method by which the space between wiring lines is completely cavitated like this embodiment. In particular, in case of the cavity layer having a cavity ration which is not smaller than 60%, since oxidation of the first titanium layer and the second titanium layer serving as the side wall portion of the cavity layer is facilitated through cavities, titanium oxide is apt to be formed, and an effect of improving the insulating resistance properties is considerable. Therefore, even in a case where the space between the wiring lines is filled with an insulating film having a cavity ratio which is not smaller than 60%, application of this embodiment is effective.

Furthermore, FIG. 9 is a cross-sectional view showing a configuration of a semiconductor device according to a modification of Embodiment 1 of the present invention. In the modification of Embodiment 1, as shown in FIG. 9, the second interlayer insulating film 200 is formed on the upper surface of the first wiring layer 110. In Embodiment 1 shown in FIG. 1, the first anti-diffusion film 170 is formed on the upper surface of the first wiring layer 110, and the second interlayer insulating film 200 is formed on the upper surface of this first anti-diffusion film 170. However, as shown in FIG. 9, the first anti-diffusion film 170 is not formed but the second interlayer insulating film 200 may be directly formed on the upper surface of the first wiring layer 110. Other structures and effects of the modification are the same as those of Embodiment 1.

In Embodiment 1 and the modification according to the present invention, the inter-wiring structure with a high cavity ratio can be used to realize the highly reliable multilayer wiring configuration and manufacturing method which can sufficiently avoid electrical short circuit between wiring lines adjacent to each other.

### Embodiment 2

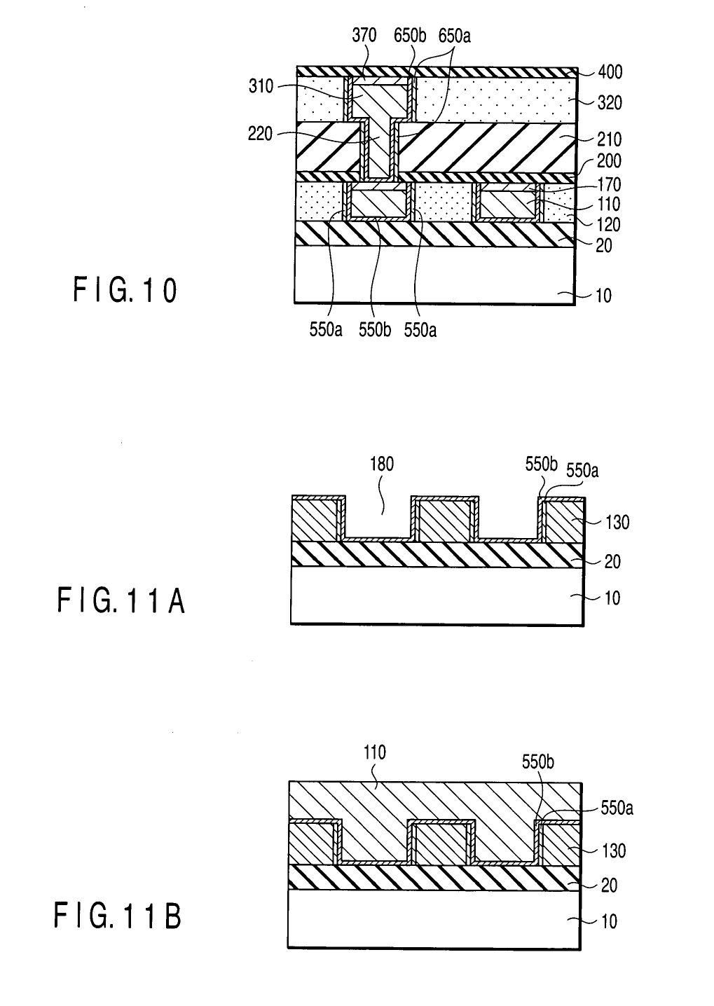

Embodiment 2 according to the present invention will now be described with reference to FIGS. 10 to 17.

Embodiment 1 uses the three-layer configuration in which the titanium layer is formed as the barrier metal layer on the side wall portion of the wiring layer, the titanium layer is formed as the oxygen barrier layer and the titanium oxide layer is formed as the insulating layer. As different from Embodiment 1, Embodiment 2 uses a two-layer configuration in which a tantalum layer is used as a barrier metal layer and a silicon nitride layer is formed as an oxygen barrier layer and an insulating layer.

FIG. 10 is a cross-sectional view schematically showing a configuration of a semiconductor device according to Embodiment 2 of the present invention. In the following drawings, like reference numerals denote parts equal to those in Embodiment 1.

A configuration of the semiconductor device according to Embodiment 2 is as follows. For example, an element or the like (not shown) formed of, e.g., a transistor, a capacitor, an element isolation region and others is provided on a substrate 10 made from, e.g., silicon. An upper side of this element is covered with a first interlayer insulating film 20 formed of, e.g., a silicon oxide film having a film thickness of, e.g., approximately 500 nm, and flattened.

On this first interlayer insulating film 20, a first wiring layer 110 and a first cavity layer 120 are provided in the same level layer to form a first wiring level.

A first tantalum layer 550b is provided on a side wall and a bottom portion of the first wiring layer 110, and a first silicon nitride layer 550a is provided on a side wall portion alone of the first wiring layer 110 which is in contact with the first cavity layer 120. This first silicon nitride layer 550a has an effect as an oxygen barrier layer and an effect of improving insulating resistance properties between wiring lines adjacent to each other.

A first anti-diffusion layer 170 is provided at an upper end of the first wiring layer 110. This first anti-diffusion layer 170 has an effect of suppressing diffusion of, e.g., copper which is a wiring portion material forming the first wiring layer 110.

An upper end of the first anti-diffusion layer 170 is set to be level with the first cavity layer 120. Upper sides of the first wiring layer 110 and the first cavity layer 120 are covered with a second interlayer insulating film 200, and flattened. With the above-described arrangement, the first wiring level is constituted.

A first silicon base oxide film 210 having a low dielectric constant is deposited on the second interlayer insulating film 200. A plug member 220 having copper or the like embedded therein is provided above the first anti-diffusion film 170 in the first silicon base oxide film 210.

A second wiring level having a second wiring layer 310 and a second cavity layer 320 is provided on the first silicon base oxide film 210.

The second wiring layer 310 is electrically connected with the first wiring layer 110 through the plug member 220 and the first anti-diffusion film 170.

A second tantalum layer 650b as a barrier metal layer suppressing diffusion of copper is provided on a side wall part of the plug member on the side which is in contact with copper embedded in the plug member 20, and a second silicon nitride layer 650a as an oxygen barrier layer and an insulating layer is provided on the side wall part on the outer side.

The second wiring level has the same configuration as that of the first wiring level. Specifically, the second tantalum layer 650b is provided on the side wall and the bottom portion of the second wiring layer 310. The second silicon nitride layer 650a is provided on the side wall part alone of the second wiring layer 310 which is in contact with the second cavity layer 320. This second silicon nitride layer 650a has an effect as the oxygen barrier layer and an effect of improving insulating resistance properties between wiring lines adjacent to each other.

A second anti-diffusion film 370 having an effect of suppressing diffusion of copper or the like is provided at an upper end of the second wiring layer 310.

The upper end of the second anti-diffusion layer 370 is set to be level with the second cavity layer 320. Upper sides of the second wiring layer 310 and the second cavity layer 320 are covered with a third interlayer insulating film 400, and flattened. With the above-described arrangement, the second wiring level is constituted.

A manufacturing method of the semiconductor device according to this embodiment will now be described with reference to process cross-sectional views of FIGS. 11A to 16. In these process cross-sectional views, the same processing steps as those in Embodiment 1 are eliminated, and a description will be given solely as to processing steps directly concerning a multilayer wiring forming method according to this embodiment.

The processing steps from the beginning to FIG. 2B are the same as those in Embodiment 1, thereby eliminating an explanation thereof.

Reference will now be made to FIG. 11A. The first silicon nitride layer 550a is deposited and formed on an entire surface including a bottom wall portion and a side wall portion of a groove portion 180 formed in a dummy film made of the first carbon film 130.

Then, when etching is performed by using an anisotropic dry etching method or the like, a silicon nitride layer formed on the bottom portion of the groove portion on the first carbon film 130 is removed, and the first silicon nitride layer 550a is left on the side wall portion alone.

Subsequently, the first tantalum film 550b serving as a barrier metal is deposited and formed on the entire surface of the groove portion 180 having the silicon nitride layer 550a being left on the side wall thereof (see FIG. 11A). At this time, the first silicon nitride layer 550a has an effect of suppressing short circuit between wiring lines and an effect of suppressing oxidation of tantalum as a diffusion barrier layer for oxygen when performing a heat treatment later.

As a method of forming a laminated structure made of two layers, i.e., the first silicon nitride layer 550a and the first tantalum layer 550b, it is preferable to use an ALCVD (Atomic Layer CVD) method or a sputtering method by which these layers are uniformly deposited on the bottom portion and the side wall portion of the groove portion. Further, as a film thickness of each of the first silicon nitride layer 550a and the first tantalum layer 550b, approximately 5 nm is preferable. Here, since a relative dielectric constant of the first silicon nitride layer 550a is as high as approximately 7, it is preferable to reduce its film thickness as much as possible in order to suppress an inter-wiring capacitance. In case of forming the first tantalum layer 550b by using the sputtering method, a film thickness of approximately 5 nm allows sufficient formation of the film.

Then, the electrocondutive first wiring film 110 made from, e.g., copper is deposited on the first tantalum layer 550b to completely fill the groove portion 180 (see FIG. 11B).

Subsequently, a surface of the first wiring layer 110 is flattened by using a CMP method or the like until the first wiring layer 110 becomes level with an upper end of the first carbon film 130. At this time, the first tantalum layer 550b deposited on the first carbon film 130 is removed.

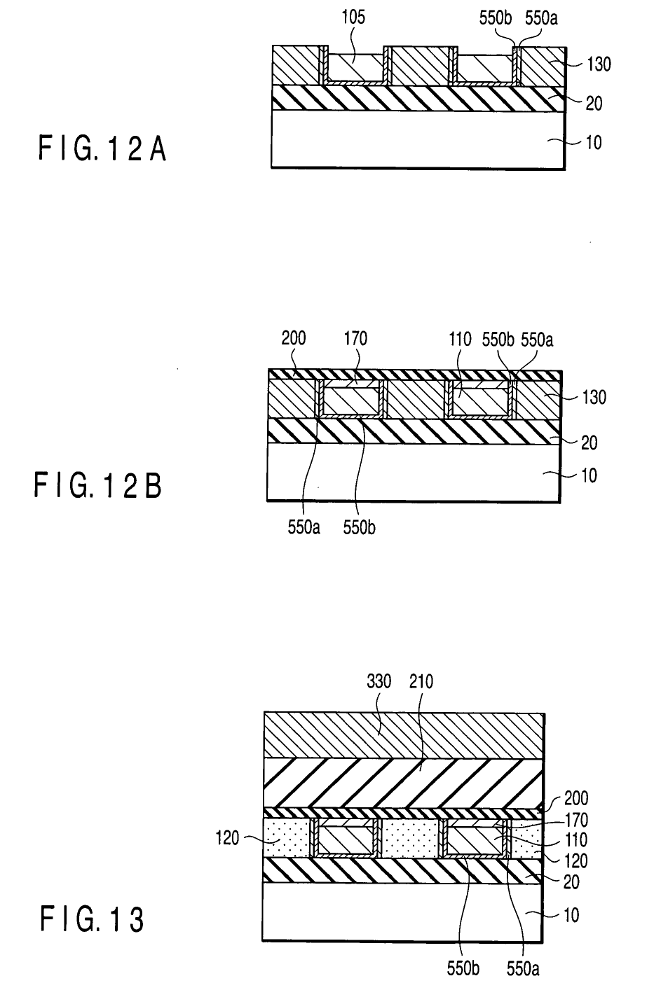

Then, the recess process is performed with respect to an upper end portion of the first wiring layer 110 like Embodiment 1 to form a recess which is approximately 20 to 30 nm at the upper end portion of the first wiring layer 110 (see FIG. 12A).

Subsequently, like Embodiment 1, the first anti-diffusion film 170 serving as an anti-diffusion film for copper as a wiring material is selectively deposited on the upper end portion of the first wiring layer 110 etched by the recess process. As this anti-diffusion film 170, Co is used, for example. Furthermore, besides Co, it is possible to use CoW, CoWB, CoWP, an SiN film, an SiCN film or an SiC film as the first anti-diffusion film 170.

Then, the second interlayer insulating film 200 is deposited on upper surfaces of the first anti-diffusion film 170 and the first carbon film 130 (see FIG. 12B). Here, as the second interlayer insulating film 200, a film which has a low relative dielectric constant and mechanical strength to withstand a weight of the second wiring layer or the like formed on the second interlayer insulating film is preferable. For example, as the second interlayer insulating film, a silicon oxide film or the like is deposited on the entire surfaces.

Here, a heat treatment is applied to the semiconductor substrate 10 in an oxygen atmosphere. Based on this heat treatment, the first carbon film 130 is vaporized through the second interlayer insulating film 200 to form the first cavity layer 120. In this heat treatment, as a diffusion barrier of oxygen, the first silicon nitride layer 550a which is in contact with the first carbon film 130 suppresses oxidation of copper constituting the first tantalum layer 550b and the first wiring layer 110. When the first silicon nitride layer 550a is formed in a boundary region with respect to the first cavity layer 120 in this manner, the first carbon film 130 is not completely vaporized in the first cavity layer 120, and a small amount of the conductive material remains on the side wall or the upper end and lower end portions of the first cavity layer 120. Even if such a small amount of the conductive material can be a factor of short circuit between wiring lines, there can be obtained an effect of improving insulating properties between two adjacent wiring layers provided at both ends of the first cavity layer 120. That is, forming the first silicon nitride layer 550a on the side wall between the wiring lines can obtain an effect of improving reliability of the wiring lines without occurrence of short circuit or the like between the wiring lines.

Thereafter, the first silicon base oxide film 210 using methyl siloxane or the like is formed on the second interlayer insulating film 200, and the second carbon film 330 having a film thickness of approximately 200 nm is sequentially formed on the first silicon base oxide film 210 (see FIG. 13).

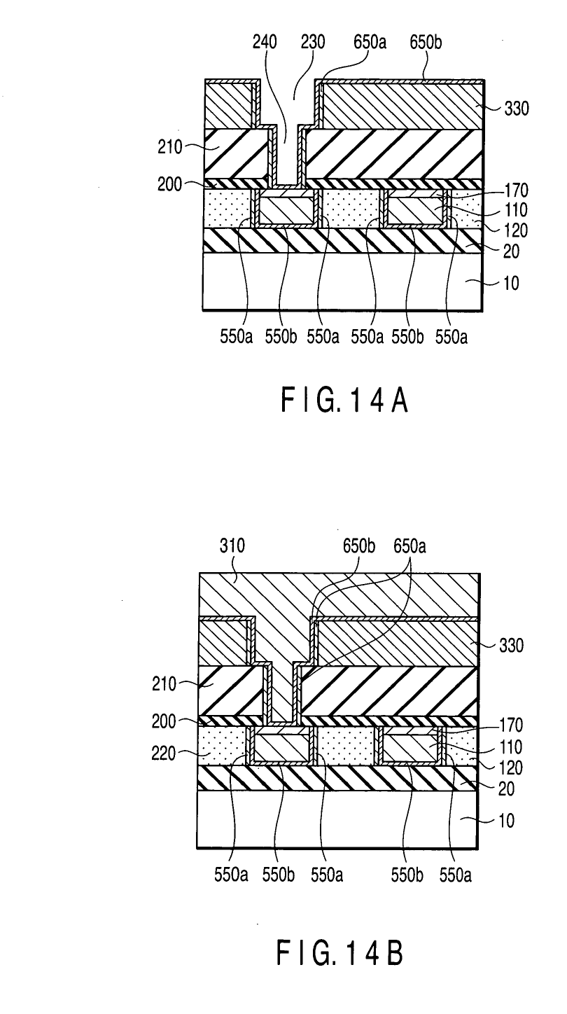

Subsequently, as shown in FIG. 14A, the groove portion 230 required to form the second wiring layer is formed in the second carbon film 330. Furthermore, the connection hole 240 required to form the plug member is formed in the first silicon base oxide film 210 and the second interlayer insulating film 200. This connection hole 240 is formed immediately above the first wiring layer 110 and the first anti-diffusion film 170 and has a shape reaching the first anti-diffusion film 170.

Moreover, the second silicon nitride layer 650a is deposited and formed on an entire surface including inner walls of the groove portion 230 and the connection hole 240, and the silicon nitride layer on bottom portions of the groove portion 230 and the connection hole 240 is removed by an anisotropic etching method so that the second silicon nitride layer 650a remains on the side wall portion alone.

Then, the second tantalum layer 650b is deposited and formed on an entire surface including inner walls of the groove portion 230 and the connection hole 240

Subsequently, the second wiring layer 310 which is made from, e.g., copper and serves as the second wiring layer is deposited on the entire upper surface of the second tantalum layer 650b (see FIG. 14B).

Then, the second wiring layer 310 is flattened by using CMP or the like until the second wiring layer 310 becomes level with the upper end portion of the second carbon film 330. At this time, the second tantalum layer 650b on the second carbon film 330 is removed.

Further, the recess process is performed with respect to the upper end portion of the second wiring layer 310 to selectively deposit the second anti-diffusion film 370 serving as an anti-diffusion film of copper.

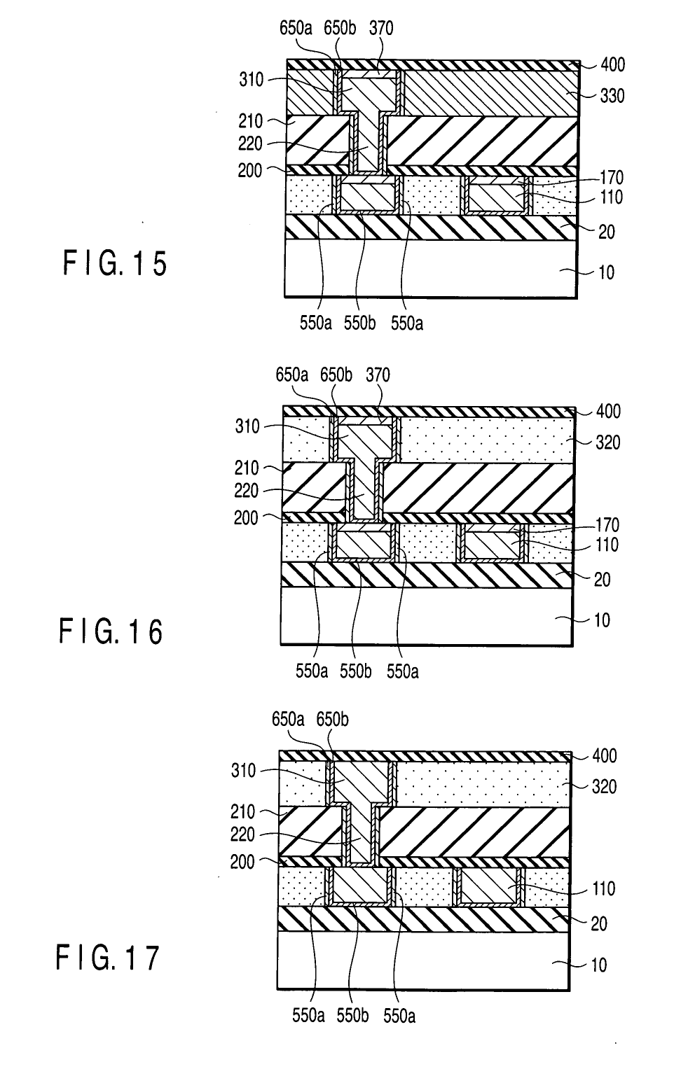

Then, a third interlayer insulating film 400 is formed on entire upper surfaces of the second anti-diffusion film 370 and the second carbon film 330 (see FIG. 15).

Subsequently, a heat treatment is performed with respect to the semiconductor substrate 10 in an oxygen atmosphere. The second carbon film 330 is burned by this heat treatment, thereby forming the second cavity layer 320.

Although the description has been given as to the case where the two wiring layers are provided in this embodiment, the present invention can be applied to a single wiring layer. In case of three or more wiring layers, multiple wiring layers made of three or more layers can be formed by repeating the steps shown in FIGS. 11A to 16.

According to the method of this embodiment, when the silicon nitride film is formed on the side wall of the wiring layer which is in contact with the cavity layer in each wiring layer, electrical short circuit can be prevented from occurring between the wiring layers adjacent to each other with the cavity layer therebetween.

Furthermore, although the description has been given as to the case where the space between the wiring lines is cavitated by the heat treatment using the carbon film in this embodiment, the present invention is not restricted to the method which completely cavitates the space between the wiring lines like this embodiment. In particular, since the efficient is considerable when the cavity layer has a cavity ratio which is not smaller than 60%, the present invention is effective when the space between the wiring lines is filled with an insulating film having a cavity ratio which is not smaller than 60%.

This embodiment has the same effect as Embodiment 1. Moreover, the three-layer film is deposited on the side wall portion of the wiring layer in Embodiment 1, but Embodiment 2 uses the two-layer structure, thereby simplifying the film formation steps as compared with Embodiment 1.

Additionally, FIG. 17 is a cross-sectional view showing a configuration of a semiconductor device according to a modification of Embodiment 2 of the present invention. In the modification of Embodiment 2, as shown in FIG. 17, the second interlayer insulating film 200 is formed on the upper surface of the first wiring layer 110. In Embodiment 2 shown in FIG. 10, the first anti-diffusion film 170 is formed on the upper surface of the first wiring layer 110, and the second interlayer insulating film 200 is formed on the upper surface of this first anti-diffusion film 170. However, as shown in FIG. 17, the first anti-diffusion film 170 may not be formed but the second interlayer insulating film 200 may be directly formed on the upper surface of the first wiring layer 110. Other structures and effects of the modification are the same as those of Embodiment 2.

In Embodiment 1 and the modification according to the present invention, the inter-wiring structure having a high cavity ratio can be used to realize the multilayer wiring structure and the manufacturing method having high reliability which can sufficiently prevent electrical short circuit between wiring lines adjacent to each other.

It is to be noted that the present invention is not restricted to the above-described structure, and various modifications can be carried out. For example, in Embodiment 2, the first and second silicon nitride layers 550a and 650a are not restricted to the silicon nitride film, and other materials having excellent insulating resistance properties and an effect of an oxygen barrier can be adopted. For example, it is possible to use tantalum nitride, aluminum nitride, silicon oxide, silicon carbide or the like. Additionally, it is possible to use a film containing, e.g., titanium or aluminum as long as it is a material which can avoid diffusion of copper into an interlayer film in place of the first and second tantalum layers 550b and 650b. Further, the structures and the processes described in Embodiment 1 or Embodiment 2 can be appropriately combined to be carried out.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general invention concept as defined by the appended claims and their equivalents.

What is claimed is:

1. A semiconductor device comprising:
a plurality of wiring layers made from a conductive material which are formed in the same level layer on a substrate;
a plurality of cavity layers formed in the same level layer as the plurality of wiring layers, the plurality of cavity layers having a cavity ratio which is not smaller than 60%;
an interlayer insulating film formed on the plurality of wiring layers and on the plurality of cavity layers; and
a barrier metal, an oxygen barrier layer and an insulating layer formed on side walls of the plurality of wiring layers.

2. The semiconductor device according to claim 1, wherein the cavity layers are formed of cavities and a film containing at least one material selected from carbon and silicon, if the cavity layers have a cavity ratio which is smaller than 100%.

3. The semiconductor device according to claim 1, wherein the barrier metal, the oxygen barrier layer and the insulating layer are arranged on the side walls of the plurality of wiring layers in the order from the wiring layer side.

4. The semiconductor device according to claim 1, wherein the oxygen barrier layer is formed of a film containing at least one material selected from titanium nitride, aluminum nitride, tantalum nitride, tungsten nitride silicon nitride, and silicon carbide.

5. The semiconductor device according to claim 1, wherein the insulating layer is formed of a film containing at least one material selected from titanium oxide, tantalum oxide, aluminum oxide, silicon nitride, silicon oxide and silicon carbide.

6. The semiconductor device according to claim 1, wherein the plurality of wiring layers are made up of a film containing copper, and the barrier metal is formed of a film containing at least one material selected from titanium, titanium nitride, tantalum and tantalum nitride.

7. The semiconductor device according to claim 1, further comprising:
an anti-diffusion film formed on upper surfaces of the plurality of wiring layers.

8. A semiconductor device comprising:
a plurality of first wiring layers formed in a first level layer on a substrate;
a first barrier metal, a first oxygen barrier layer and a first insulating layer formed on side walls of the plurality of first wiring layers;
a plurality of first cavity layers formed between the plurality of first wiring layers, the first cavity layers having a cavity ratio which is not smaller than 60%;
a plurality of second wiring layers formed in a second level layer above the first level layer on the substrate;
a second barrier metal, a second oxygen barrier layer and a second insulating layer formed on side walls of the plurality of second wiring layers;
a plurality of second cavity layers formed between the plurality of second wiring layers, the second cavity layers having a cavity ratio which is not smaller than 60%;
an interlayer insulating film formed between the first level layer and the second level layer, the interlayer insulating film insulating the plurality of first wiring layers and the plurality of second wiring layers from each other; and
a plug member formed in the interlayer insulating film, the plug member electrically connecting the first wiring layers and the second wiring layers with each other.

9. The semiconductor device according to claim 8, wherein the cavity layers are formed of cavities and a film containing at least one material selected from carbon and silicon, if the cavity layers have a cavity ratio which is smaller than 100%.

10. The semiconductor device according to claim 8, wherein the first barrier metal, the first oxygen barrier layer and the first insulating layer are arranged on the side walls of the plurality of first wiring layers in the order from the first wiring layer side, and the second barrier metal, the second oxygen barrier layer and the second insulating layer are arranged on the side walls of the plurality of second wiring layers in the order from the second wiring layer side.

11. The semiconductor device according to claim 8, wherein the first and second oxygen barrier layer are formed of a film containing at least one material selected from titanium nitride, aluminum nitride, tantalum nitride, tungsten nitride silicon nitride and silicon carbide.

12. The semiconductor device according to claim 8, wherein the first and second insulating layer are formed of a film containing at least one material selected from titanium oxide, tantalum oxide, aluminum oxide, silicon nitride, silicon oxide and silicon carbide.

13. The semiconductor device according to claim 8, wherein the plurality of first and second wiring layers are made up of a film containing copper, and the first and second barrier metal are formed of a film containing at least one material selected from titanium, titanium nitride, tantalum and tantalum nitride.

14. The semiconductor device according to claim 8, further comprising:
anti-diffusion films formed on upper surfaces of the plurality of first and second wiring layers.

15. The semiconductor device according to claim 8, further comprising:
the second barrier metal, the second oxygen barrier layer and a conductive layer formed on a side wall of the plug member.

16. The semiconductor device according to claim 15, wherein the second barrier metal, the second oxygen barrier layer and the conductive layer are arranged on the side wall of the plug member in the order from the plug member side.

17. A manufacturing method of a semiconductor device, comprising:
forming a dummy film on a substrate;
forming a wiring groove in the dummy film;
forming a metal layer on a side wall in the wiring groove;
forming an oxygen barrier layer on the metal layer on the side wall in the wiring groove;
forming a barrier metal on the oxygen barrier layer on the side wall in the wiring groove;
forming a wiring layer on the barrier metal in the wiring groove;
forming an interlayer insulating film above the wiring layer; and
vaporizing the dummy film by a heat treatment after formation of the interlayer insulating film to form a cavity layer having a cavity ratio which is not smaller than 60%, and oxidizing the metal layer to form an insulating layer.

18. The semiconductor device according to claim 17, wherein the heat treatment is performed in an oxygen atmosphere.
